(19) United States
(12) Patent Application Publication
(10) Pub. No.: US 2026/0239899 A1
(43) Pub. Date: Aug. 13, 2026

(54) METHOD OF FORMING A GATE STACK INCLUDING A DIELECTRIC LAYER

(71) Applicant: ASM IP Holding B.V., Almere (NL)

(72) Inventors: Rohit Abraham John, Chandler, AZ (US); Fu Tang, Gilbert, AZ (US); Eric James Shero, Phoenix, AZ (US)

(21) Appl. No.: 19/467,911

(22) Filed: Feb. 3, 2026

Related U.S. Application Data
(60) Provisional application No. 63/754,704, filed on Feb. 6, 2025.

(51) Int. Cl. H10P 14/60; C23C 16/40; C23C 16/455; H10D 64/01; H10P 14/692

(52) U.S. Cl. CPC H10P 14/6339; C23C 16/401; C23C 16/405; C23C 16/45529; H10D 64/01332; H10P 14/69391; H10P 14/69392; H10P 14/69395

(57) ABSTRACT

A method for forming a gate stack includes providing a substrate, optionally forming an interfacial layer, forming a dielectric layer, and optionally forming a dipole layer, where the dielectric layer comprises hafnium, zirconium, and oxygen, and at least one of silicon or aluminum.

### CROSS-REFERENCE TO RELATED APPLICATIONS

This application is a nonprovisional of, and claims priority to and the benefit of, U.S. Provisional Patent Application No. 63/754,704, filed Feb. 6, 2025 and entitled “METHOD OF FORMING A GATE STACK INCLUDING A DIELECTRIC LAYER,” which is hereby incorporated by reference herein.

### FIELD

The disclosure generally relates to methods of forming electronic devices. More particularly, examples are described that relate to a method for forming a gate stack suitable for use with transistors, as well as to a structure comprising a gate stack and a substrate processing apparatus for forming a gate stack including a dielectric layer.

### BACKGROUND

The scaling of semiconductor devices has led to significant improvements in speed and density of integrated circuits. The scaling of semiconductor devices, however, has presented challenges. For example, during the formation of field effect transistors, such as metal oxide field effect transistors, forming gate stacks with dielectric layers that maintain relatively high dielectric constants (high-k materials), while maintaining relatively low equivalent oxide thickness (EOT) or capacitance equivalence thickness (CET) and leakage current has been challenging.

High-k materials may exhibit desirable electrical properties for the functionality of gate stacks. However, current high-k materials may not exhibit desired dielectric constant, while maintaining other desired electrical properties, such as high band gap to allow relatively low EOT or CET in the gate stacks. Thus, there exists a desire for improved dielectric layers and improved methods for forming dielectric layers and gate stacks that maintain desirable properties and that can be formed with accuracy and precision.

Any discussion, including discussion of problems and solutions, set forth in this section has been included in this disclosure solely for the purpose of providing a context for the present disclosure. Such discussion should not be taken as an admission that any or all of the information was known at the time the invention was made or otherwise constitutes prior art.

### SUMMARY

This summary is provided to introduce a selection of concepts in a simplified form. These concepts are described in further detail in the detailed description of example embodiments of the disclosure below. This summary is not intended to necessarily identify key features or essential features of the claimed subject matter, nor is it intended to be used to limit the scope of the claimed subject matter.

Various examples described herein provide a method for forming a gate stack, and, for forming a dielectric layer in a gate stack. The methods disclosed herein provide gate stacks with dielectric layers having desired properties, such as high dielectric constants (e.g., above 12) and high band gaps (e.g., greater than about 5 eV or about 6 eV or greater than 8 eV), for use in gate stacks with relatively low CET (e.g., below 16 Angstroms or below 14 Angstroms).

According to one or more embodiments, a method of forming a gate stack, which includes forming a dielectric layer, is provided. An exemplary method includes providing a substrate in a reaction chamber. The exemplary method continues with forming a dielectric layer by a cyclical deposition process. In some embodiments, the cyclical deposition method is an atomic layer deposition (ALD) method. In the exemplary method, forming the dielectric layer includes pulsing a hafnium precursor a plurality of times, pulsing a zirconium precursor at least once, pulsing an additive precursor at least once, and pulsing an oxygen reactant. In some embodiments, the additive precursor comprises a silicon precursor. In some embodiments, the additive precursor comprises an aluminum precursor.

In some embodiments, an interfacial layer is formed on a surface of a substrate. The interfacial layer can be formed, for example, by a cyclical deposition process or oxidation of the surface of the substrate. In some embodiments, the interfacial layer includes a semiconductor oxide, such as silicon oxide. In some embodiments, the interfacial layer includes SiO₂ or a crystalline SiO₂. In some embodiments, the interfacial layer has a thickness of about 2 to 10 Angstroms, or about 2 to 7 Angstroms.

In some embodiments, the dielectric layer is formed (e.g., directly) on the interfacial layer. In some embodiments, the dielectric layer is formed (e.g., directly) on a dipole layer. The dielectric layer can include hafnium, zirconium, silicon, and oxygen. In some embodiments, the dielectric layer can further include aluminum. In some embodiments, the dielectric layer can include hafnium, zirconium, aluminum, and oxygen. In some embodiments, the dielectric layer comprises a hafnium silicon oxide doped with zirconium, a hafnium aluminum oxide doped with zirconium, or a hafnium silicate doped with zirconium. In some embodiments, the dielectric layer may comprise a plurality of sub-layers. The dielectric layer may comprise sub-layers of hafnium oxide, silicon oxide, aluminum oxide, and/or zirconium oxide. In some embodiments, sub-layers comprising silicon oxide and/or aluminum oxide and sub-layers comprising zirconium oxide are separated by at least one sub-layer comprising hafnium oxide. In some embodiments, the dielectric layer comprises a first hafnium oxide sub-layer, a silicon oxide sub-layer or aluminum oxide sub-layer, a second hafnium oxide sub-layer, and a zirconium oxide sub-layer, where either the silicon oxide sub-layer or aluminum oxide sub-layer and the zirconium oxide sub-layer are not in direct contact with each other. The dielectric layer may include a hafnium oxide sub-layer between each zirconium oxide sub-layer and silicon oxide sub-layer or aluminum oxide sub-layer.

In some embodiments, the dielectric layer is or comprises a bilayer and includes a first sub-layer and a second sub-layer. In some embodiments, the first sub-layer includes a hafnium silicate, hafnium silicon oxide, or a hafnium aluminum oxide. In some embodiments, the first sub-layer is disposed (e.g., directly) on the interfacial layer. In some embodiments, the first sub-layer is disposed (e.g., directly) on a dipole layer. In some embodiments, the second sub-layer includes a zirconium oxide, zirconium silicon oxide, zirconium aluminum oxide, or zirconium silicate. In some embodiments, the second sub-layer is disposed (e.g., directly) on the first sub-layer.

In some embodiments, during formation of the dielectric layer, the hafnium precursor is pulsed at least once between each pulse of the zirconium precursor and each pulse of the additive precursor. In some embodiments, forming the dielectric layer includes performing one or more of a first cycle. In some embodiments, the first cycle includes, in order, pulsing the hafnium precursor for a first period, pulsing the additive precursor, pulsing the hafnium precursor for a second period, and pulsing the zirconium precursor. In some embodiments, the zirconium precursor is not pulsed before the second period in each first cycle. In some embodiments, the additive precursor is not pulsed before the first period or after the second period in each first cycle.

In some embodiments, during formation of the dielectric layer, a ratio of number of pulses of the additive precursor to a number of pulses of the zirconium precursor in the first cycle is in the range of about 2.5:1 to about 4:1, or about 2.7:1 to about 3.5:1, or about 2.9:1 to about 3.2:1. A ratio of number of pulses of the hafnium precursor to a number of pulses of the zirconium precursor in the first cycle may be in the range of about 1.5:1 to about 2.5:1, or about 1.7:1 to about 2.3:1, or about 1.9:1 to about 2.1:1. A ratio of a number of pulses of the additive precursor to a number of pulses of the hafnium precursor in the first cycle may be in the range of about 1.25:1 to 1.75:1, or about 1.4:1 to about 1.6:1.

In some embodiments, during the formation of the dielectric layer, a ratio of a number of pulses of hafnium precursor to a number of pulses of the zirconium precursor during forming the dielectric layer is about 30:1 to about 7:1, or about 20:1 to about 10:1.

The precursors and reactants may be any suitable precursors or reactants. In some embodiments, the hafnium precursor comprises a hafnium halide or a metalorganic hafnium precursor. In some embodiments, the zirconium precursor comprises a zirconium halide or a metalorganic zirconium precursor. In some embodiments, the silicon precursor comprises a silane, a chlorosilane, an organic silane, a heterosilane, or a silicon halide. In some embodiments, the aluminum precursor comprises triethylaluminun (TEA), trimethylaluminun (TMA), dimethylaluminum hydride (DMAH), and aluminum chloride. In some embodiments, the oxygen reactant comprises one or more of H₂O, O₂, O₃, H₂O₂, NO, NO₂, or N₂O, in any combination.

In some embodiments, the dielectric layer has a thickness between about 15 Angstroms and about 25 Angstroms, or between about 16 Angstroms and about 20 Angstroms, or between about 12 Angstroms to about 16 Angstroms. In some embodiments, the dielectric layer has a dielectric constant greater than about 12, or between about 12 and 30, or between about 12 and 24, or between about 12 and 15, or between about 18 and 22.

In some embodiments, the method includes forming a dipole layer. In some embodiments, the dipole layer comprises a metal oxide, a metal nitride, or a metal oxynitride. In some embodiments, the dipole layer comprises lanthanum, aluminum, yttrium, scandium, and/or gallium. In some embodiments, the dipole layer includes lanthanum oxide, aluminum oxide, yttrium oxide, scandium oxide, or gallium oxide. In some embodiments, the dipole layer may be formed (e.g., directly) on the dielectric layer. In some embodiments, the dipole layer is disposed directly on the second sub-layer of the dielectric layer. In some embodiments, the dielectric layer may be formed (e.g., directly) on the dipole layer, and the dipole layer may be formed (e.g., directly) on the interfacial layer. In some embodiments, the dipole layer may be formed in between sub-layers of the dielectric layer.

In accordance with further examples of the disclosure, a device is formed using a method and/or include a structure as described herein.

In accordance with yet further exemplary embodiments of the disclosure, a system is provided for performing a method and/or for forming a structure as described herein.

In accordance with various further embodiments of the disclosure, a method for forming a gate stack is provide, the method including: providing a substrate including a surface including an interfacial layer in a reaction chamber; and forming a dielectric layer on the interfacial layer by an atomic layer deposition process, wherein forming the dielectric layer includes pulsing a hafnium precursor a plurality of times, pulsing a zirconium precursor at least once, pulsing an additive precursor at least once, and pulsing an oxygen reactant, wherein the additive precursor includes a silicon precursor or an aluminum precursor, and wherein the hafnium precursor is pulsed at least once between each pulse of the zirconium precursor and each pulse of the additive precursor.

In some embodiments, the dielectric layer includes a plurality of sub-layers including a first sub-layer including hafnium oxide, a second sub-layer including silicon oxide or aluminum oxide, a third sub-layer including hafnium oxide, and a fourth sub-layer including zirconium oxide, and wherein the second sub-layer and the fourth sub-layer are not in direct contact with each other.

In some embodiments, forming the dielectric layer includes performing a plurality of first cycles, wherein the first cycle includes, in order: pulsing the hafnium precursor for a first period, pulsing the additive precursor, pulsing the hafnium precursor for a second period, and pulsing the zirconium precursor.

In some embodiments, the zirconium precursor is not pulsed before the second period, and wherein the additive precursor is not pulsed before the first period or after the second period in the first cycle.

In some embodiments, a ratio of number of pulses of the additive precursor to a number of pulses of the zirconium precursor in the first cycle is in a range of about 2.5:1 to about 4:1.

In some embodiments, a ratio of number of pulses of the hafnium precursor to a number of pulses of the zirconium precursor in the first cycle is in a range of about 1.5:1 to about 2.5:1.

In some embodiments, a ratio of a number of pulses of the additive precursor to a number of pulses of the hafnium precursor in the first cycle is in a range of about 1.25:1 to 1.75:1.

In some embodiments, the method further includes forming a dipole layer directly on the dielectric layer.

In some embodiments, the dipole layer includes lanthanum oxide, aluminum oxide, yttrium oxide, scandium oxide, or gallium oxide.

In some embodiments, the method further includes forming a dipole layer directly on the interfacial layer.

In some embodiments, a ratio of oxygen atoms to a sum of hafnium, zirconium, aluminum, and silicon atoms is in a range of about 1.6:1 to about 2.5:1.

In some embodiments, the additive precursor includes a silicon precursor.

In accordance with various additional embodiments of the disclosure, a method for forming a gate stack is provided, the method including: providing a substrate including a surface including an interfacial layer in a reaction chamber; and forming a dielectric layer on the interfacial layer by an atomic layer deposition process, wherein the dielectric layer includes a first sub-layer including hafnium silicate, hafnium silicon oxide, or hafnium aluminum oxide disposed directly on the interfacial layer and a second sub-layer including zirconium oxide, zirconium silicon oxide, or zirconium silicate disposed directly on the first sub-layer.

In some embodiments, the method further includes forming a dipole layer directly on the second sub-layer, wherein the dipole layer includes lanthanum oxide, aluminum oxide, yttrium oxide, scandium oxide, or gallium oxide.

In some embodiments, the dielectric layer has a thickness between about 15 Angstroms and about 25 Angstroms.

In some embodiments, the interfacial layer includes silicon oxide.

In some embodiments, the dielectric layer has a dielectric constant in a range of about 12 to about 30.

These and other embodiments will become readily apparent to those skilled in the art from the following detailed description of certain embodiments having reference to the attached figures; the invention not being limited to any particular embodiment(s) disclosed.

### BRIEF DESCRIPTION OF THE DRAWINGS

FIG. 1 illustrates a method for forming a gate stack in accordance with one or more embodiments of the disclosure;

FIG. 2 illustrates a method for forming a dielectric layer in accordance with one or more embodiments of the disclosure;

FIG. 3 illustrates another method for forming a dielectric layer in accordance with one or more embodiments of the disclosure;

FIG. 4 illustrates another method for forming a dielectric layer in accordance with one or more embodiments of the disclosure;

FIG. 5 illustrates an example of a substrate processing apparatus in accordance with one or more examples of the disclosure;

FIG. 6 illustrates an example of a structure that can form part of a device in accordance with one or more examples of the disclosure;

FIG. 7 illustrates another example of a structure that can form part of a device in accordance with one or more examples of the disclosure;

FIG. 8 illustrates another example of a structure that can form part of a device in accordance with one or more examples of the disclosure;

FIG. 9 illustrates another example of a structure that can form part of a device in accordance with one or more examples of the disclosure;

FIG. 10 illustrates another example of a structure that can form part of a device in accordance with one or more examples of the disclosure;

It will be appreciated that elements in the figures are illustrated for simplicity and clarity and have not necessarily been drawn to scale. For example, the dimensions of some of the elements in the figures may be exaggerated relative to other elements to help improve understanding of illustrated embodiments of the present disclosure.

### DETAILED DESCRIPTION

The description of exemplary embodiments of methods, structures, devices, and systems provided below is merely exemplary and is intended for purposes of illustration only; the following description is not intended to limit the scope of the disclosure or the claims. Moreover, recitation of multiple embodiments having stated features is not intended to exclude other embodiments having additional features or other embodiments incorporating different combinations of the stated features. For example, various embodiments are set forth as exemplary embodiments and may be recited in the dependent claims. Unless otherwise noted, the exemplary embodiments or components thereof may be combined or may be applied separate from each other.

As used herein, the term “and/or” includes any and all combinations of one or more of the associated listed items. Unless otherwise noted, expressions such as “at least one of,” when preceding a list of elements, modify the entire list of elements and do not necessarily modify the individual elements of the list.

As used herein, the singular forms “a,” “an,” and “the” are intended to include the singular and plural forms as well, unless the context indicates otherwise.

As used herein, the term “substrate” can refer to any underlying material or materials that may be used to form, or upon which, a device, a circuit, or a film may be formed. A substrate can include a bulk material, such as silicon (e.g., single-crystal silicon), other Group IV materials, such as germanium, or compound semiconductor materials, such as Group III-V or Group II-VI semiconductors, and can include one or more layers overlying or underlying the bulk material. By way of example, a substrate can include silicon or silicon germanium.

In some embodiments, “film” refers to a layer extending in a direction perpendicular to a thickness direction. In some embodiments, “layer” refers to a material having a certain thickness formed on a surface and can be a synonym of a film or a non-film structure. A film or layer may be constituted by a discrete single film or layer having certain characteristics or multiple films or layers, and a boundary between adjacent films or layers may or may not be clear and may or may not be established based on physical, chemical, and/or any other characteristics, formation processes or sequence, and/or functions or purposes of the adjacent films or layers. The layer or film can be continuous—or not. Further, a single film or layer can be formed using one or more deposition cycles.

As used herein, the term “structure” can refer to a partially or completely fabricated device structure. By way of examples, a structure can be a substrate or include a substrate with one or more layers and/or features formed thereon.

As used herein, terms including an element followed by “precursor” can refer to compounds that comprise the recited element.

As used herein, the term “overlying” can refer to two films in contact with each other.

As used herein, the term “cyclical deposition process” or “cyclic deposition process” can refer to a vapor deposition process in which deposition cycles, typically a plurality of consecutive deposition cycles, are conducted in a process chamber. Cyclic deposition processes can include, for example, cyclic chemical vapor deposition (CCVD) and/or atomic layer deposition (ALD) processes.

In this disclosure, any two numbers of a variable can constitute a workable range of the variable, and any ranges indicated may include or exclude the endpoints. Additionally, any values of variables indicated (regardless of whether they are indicated with “about” or not) may refer to precise values or approximate values and include equivalents, and may refer to average, median, representative, majority, etc. For example, values of variables may include +/−20%, or +/−10%, or +/−5%, or +/−1%, or +/−0% of the value of the listed variable. Further, in this disclosure, the terms “comprising,” “including,” “constituted by” and “having” can refer independently to “typically or broadly comprising,” “comprising,” “consisting essentially of,” or “consisting of” in some embodiments. In this disclosure, any defined meanings do not necessarily exclude ordinary and customary meanings in some embodiments.

In some embodiments, the term “dielectric” or “dielectric material” can refer to a material with a dielectric constant greater than 1, or greater than 2, or greater than 3.9, or greater than 10.

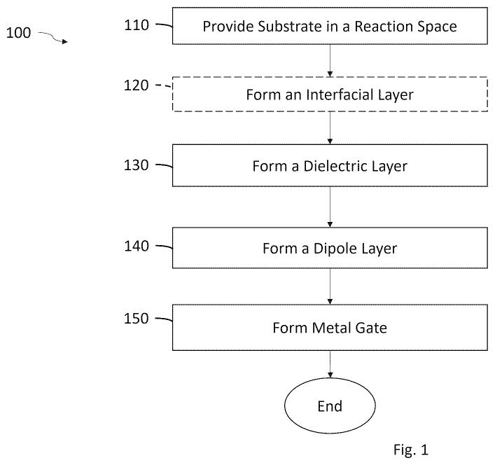

FIG. 1 illustrates a method 100 for forming a gate stack in accordance with exemplary embodiments of the disclosure. Method 100 includes the step of providing a substrate within a reaction chamber (step 110), optionally forming an interfacial layer (step 120), forming a dielectric layer (step 130), optionally forming a dipole layer (step 140), and forming a gate electrode (step 150).

During step 110, a substrate is provided into a reaction space in a reaction chamber. In accordance with examples of the disclosure, the reaction chamber can form part of a chemical vapor deposition reactor, such as a chemical vapor deposition (CVD) reactor, an atomic layer deposition (ALD) reactor, or the like. Various steps of methods described herein can be performed within a single reaction chamber or can be performed in multiple reaction chambers, such as reaction chambers of a cluster tool.

During step 110, the substrate can be brought to a desired temperature and/or the reaction space can be brought to a desired pressure, such as a temperature and/or pressure suitable for subsequent steps. By way of examples, a temperature (e.g., of a substrate, a substrate support, or an environment) within a reaction space can be between about 0° C. and about 500° C., or between about 250° C. and about 425° C. By way of examples, a pressure within a reaction space can be less than 760 torr, or between about 1 torr and 500 torr, or between about 1 torr and about 100 torr.

In some embodiments, the surface of the substrate comprises an interfacial layer. In some embodiments, the interfacial layer is disposed directly on a semiconductor material, such as silicon, single-crystal silicon, other Group IV materials, such as germanium, or compound semiconductor materials, such as silicon-germanium, Group III-V or Group II-VI semiconductors.

If the surface of the substrate does not include an interfacial layer, the method 100 comprises step 120 of forming an interfacial layer on the substrate. The interfacial layer may be formed by any suitable method. In some embodiments, the interfacial layer is formed by a (e.g., cyclical) deposition process or oxidation of the semiconductor material. In some embodiments, the interfacial layer comprises silicon oxide. In some embodiments, the interfacial layer comprises SiO₂. In some embodiments, the interfacial layer comprises crystalline SiO₂. In some embodiments, the interfacial layer has a thickness of about 2 to 10 Angstroms, or about 2 to 7 Angstroms.

The method 100 continues with forming a dielectric layer (step 130). During step 130, the substrate can be brought to a desired temperature and/or the reaction space can be brought to a desired pressure. By way of examples, a temperature (e.g., of a substrate or a substrate support) within a reaction space can be between about 200° C. and about 500° C., or between about 250° C. and about 425° C. A pressure within the reaction chamber can also be controlled. By way of examples, a pressure within a reaction space can be less than 760 torr, or between about 1 torr and 100 torr. In some embodiments, the dielectric layer is formed directly on the interfacial layer. In some embodiments, forming the dielectric material comprises a cyclical deposition process, such as an atomic layer deposition (ALD) process or a cyclical CVD process.

In some embodiments, the dielectric layer has a thickness between about 15 Angstroms and about 25 Angstroms, or between about 16 Angstroms and about 20 Angstroms. In some embodiments, the dielectric layer has a dielectric constant greater than about 12, or between about 12 and 30, or between about 12 and 24, or between about 12 and 15, or between about 18 and 22.

In some embodiments, the dielectric layer comprises hafnium, zirconium, silicon, and oxygen. In some embodiments, the dielectric layer comprises HfₓZr_{y}A_{z}O₂, where x, y, and z are in the range of 0 and about 1, and the sum of x, y, and z is in the range of about 0.8 to 1.2, or between about 0.9 and 1.1, and wherein A is aluminum, silicon, or a combination of aluminum and silicon. In some embodiments, the dielectric layer comprises a tetragonal crystal structure.

In some embodiments, the dielectric layer comprises a hafnium silicon oxide doped with zirconium, a hafnium silicate doped with zirconium, or a hafnium aluminum oxide doped with zirconium. In some embodiments, the dielectric material comprises a hafnium silicon oxide, a hafnium silicate, or a hafnium aluminum oxide with zirconium replacing a number of the hafnium atoms in its crystal structure. In some embodiments, the dielectric layer may comprise a plurality of sub-layers. In some embodiments, the dielectric layer may comprise one or more sub-layers of hafnium oxide, silicon oxide, aluminum oxide, and/or zirconium oxide. In some embodiments, sub-layers comprising silicon oxide or aluminum oxide and sub-layers comprising zirconium oxide are separated by at least one sub-layer comprising hafnium oxide. In some embodiments, the dielectric layer comprises a first hafnium oxide sub-layer, a silicon oxide sub-layer or aluminum oxide sub-layer, a second hafnium oxide sub-layer, and a zirconium oxide sub-layer, where either the silicon oxide sub-layer or aluminum oxide sub-layer and the zirconium oxide sub-layer are not in direct contact with each other. The dielectric layer may include a hafnium oxide sub-layer between each zirconium oxide sub-layer and silicon oxide sub-layer or aluminum oxide sub-layer.

In some embodiments, the dielectric layer comprises a first sub-layer and a second sub-layer. In some embodiments, the first sub-layer comprises a hafnium silicate, hafnium silicon oxide, or hafnium aluminum oxide. In some embodiments, the first sub-layer is disposed directly on the interfacial layer. In some embodiments, the second sub-layer includes a zirconium oxide, zirconium silicon oxide, or zirconium silicate. In some embodiments, the second sub-layer is disposed directly on the first sub-layer. In some embodiments, the dielectric layer consists of the first sub-layer and the second sub-layer.

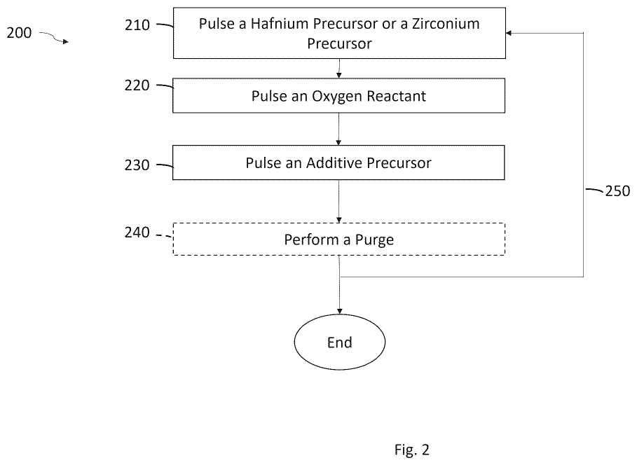

FIG. 2 illustrates a method 200 suitable for step 130 in FIG. 1. Method 200 may produce a dielectric layer comprising a hafnium silicon oxide doped with zirconium, a hafnium silicate doped with zirconium, or a hafnium aluminum oxide doped with zirconium. Method 200 may produce a dielectric layer comprising a hafnium silicon oxide, a hafnium silicate, or hafnium aluminum oxide where about 5-10 at % of the hafnium in the hafnium silicon oxide, a hafnium silicate, or hafnium aluminum oxide is replaced with zirconium. Method 200 comprises pulsing a hafnium precursor or a zirconium precursor (sub-step 210), pulsing an oxygen reactant (sub-step 220), pulsing an additive precursor (sub-step 230) comprising an aluminum precursor or a silicon precursor, optionally performing one or more purges 240, and optionally repeating the steps one or more times (loop 250). The sub-steps 210-240 of method 200 may be performed in any order. Each sub-step 210-240 of method 200 may be performed once or a plurality of times. In some embodiments, a purge 240 is performed after any or all of the sub-steps 210-230 of pulsing a hafnium precursor or a zirconium precursor (sub-step 210), pulsing an oxygen reactant (sub-step 220), and pulsing an additive precursor (sub-step 230). In some embodiments, a pulse of oxygen reactant (sub-step 220) is performed after a pulse of a hafnium precursor or a zirconium precursor (sub-step 210), or an additive precursor (sub-step 230). In some embodiments, a ratio of a number of pulses of hafnium precursor to a number of pulses of the zirconium precursor during forming the dielectric layer is about 30:1 to about 7:1, or about 20:1 to about 10:1. In some embodiments, a ratio of the number of hafnium atoms to zirconium atoms in the dielectric layer is between about 20:1 to about 10:1, or between about 30:1 to about 7:1, or about 20:1 to about 10:1. In some embodiments, sub-steps 210-240 constitute a first process cycle. In some embodiments, the first process cycle is repeated a plurality of times. In some embodiments where a plurality of first process cycles are performed, a number of first process cycles comprising pulsing a zirconium precursor to a number of first process cycles comprising pulsing a hafnium precursor is about 1:10 to about 1:20. In some embodiments, the dielectric layer formed by the method 200 has a formula of HfₓZr_{y}A_{z}O₂, where x, y, and z are between 0 and about 1, the sum of x, y, and z is in the range of about 0.8 to 1.2, and x is about 10 to 20 times greater than y, and where A is aluminum, silicon or a combination of aluminum and silicon. In some embodiments, z is in the range of about 0.05 to about 0.2, or about 0.06 to about 0.14.

Not to be bound by theory, it is thought that replacing about 5-10% of hafnium with zirconium, while forming a hafnium silicate, a hafnium silicon oxide, or a hafnium aluminum oxide may increase the dielectric constant above 12, while maintaining a high band gap (e.g., above 5 eV or above 6 eV) and keeping the CET of the gate stack less than about 16 Angstroms or less than about 14 Angstroms.

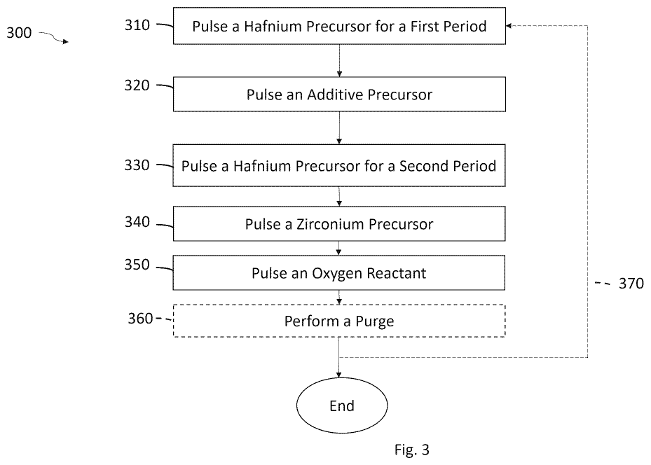

FIG. 3 illustrates another method 300 suitable for step 130 in FIG. 1. Method 300 may produce a dielectric layer comprising a hafnium silicon oxide doped with zirconium, a hafnium silicate doped with zirconium, or a hafnium aluminum oxide doped with zirconium, where zirconium and silicon or aluminum are separated, such as separated by hafnium. Method 300 comprises pulsing a hafnium precursor for a first period 310, pulsing an additive precursor 320 comprising a silicon precursor or aluminum precursor, pulsing a hafnium precursor for a second period 330, pulsing a zirconium precursor 340, pulsing an oxygen reactant 350, optionally performing a purge, and optionally repeating the sub-step 310-360 once or a plurality of times (loop 370). In some embodiments, method 300 comprises sub-steps 310-340 performed once or a plurality of times and in any order, where at least one pulse of hafnium precursor is between a pulse of zirconium precursor and a pulse of additive precursor. In some embodiments, pulsing an oxygen reactant is performed after one or more of sub-steps 310-340. In some embodiments, pulsing an oxygen reactant is performed after one or more of sub-steps 310-340 and before another one of sub-steps 310-340 is performed. In some embodiments, a purge 360 is performed after any or all of the sub-steps 310-350. In some embodiments, sub-steps 310-360 constitute a deposition cycle. In some embodiments, the deposition cycle is repeated once or a plurality of times (loop 370).

In some embodiments, a ratio of number of pulses of the additive precursor to a number of pulses of the zirconium precursor in the first cycle is in the range of about 2.5:1 to about 4:1, or about 2.7:1 to about 3.5:1, or about 2.9:1 to about 3.2:1. In some embodiments, a ratio of number of pulses of the hafnium precursor to a number of pulses of the zirconium precursor in the first cycle is in the range of about 1.5:1 to about 2.5:1, or about 1.7:1 to about 2.3:1, or about 1.9:1 to about 2.1:1. In some embodiments, a ratio of a number of pulses of the additive precursor to a number of pulses of the hafnium precursor in the first cycle is in the range of about 1.25:1 to 1.75:1, or about 1.4:1 to about 1.6:1.

In some embodiments, forming the dielectric layer includes performing one or more of a first cycle. In some embodiments, the first cycle comprises, in order, pulsing the hafnium precursor for a first period, pulsing the additive precursor, pulsing the hafnium precursor for a second period, and pulsing the zirconium precursor. In some embodiments, the zirconium precursor is not pulsed before the second period in each first cycle. In some embodiments, the additive precursor is not pulsed before the first period or after the second period in each first cycle. In some embodiments, the first cycle comprises pulsing the hafnium precursor for a first period exactly once, pulsing the additive precursor exactly three times, pulsing the hafnium precursor for a second period exactly once, and pulsing the zirconium precursor exactly once.

Not to be bound by theory, it is thought that the presence of a zirconium to silicon or aluminum interface or the presence of a zirconium silicate, zirconium silicon oxide, or zirconium aluminum oxide sub-layer may lower the dielectric constant of the dielectric layer. To prevent the formation of a zirconium-silicon interface or a zirconium silicate, zirconium silicon oxide, or zirconium aluminum oxide sub-layer, pulses of zirconium precursor may be separated from pulses of additive precursor by pulses of hafnium precursor. In this instance, hafnium or hafnium oxide prevents the formation of a zirconium silicate, zirconium silicon oxide, or zirconium aluminum oxide sub-layer. In embodiments where the hafnium precursor is pulsed at least once between each pulse of the zirconium precursor and each pulse of the additive precursor, a gate structure with a dielectric layer with a dielectric constant greater than 12 and a CET of the gate stack less than about 16 A or less than about 14 A is obtained.

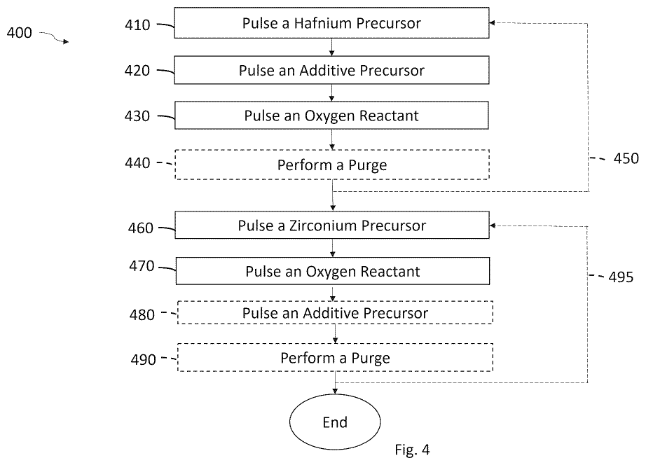

FIG. 4 illustrates another method 400 suitable for step 130 in FIG. 1. Method 400 may be used to form a dielectric layer comprising a first sub-layer and a second sub-layer. In some embodiments, the first sub-layer comprises a hafnium silicate, hafnium silicon oxide, or hafnium aluminum oxide. In some embodiments, the second sub-layer comprises a zirconium oxide, zirconium silicon oxide, or zirconium silicate. Method 400 comprises pulsing a hafnium precursor (sub-step 410), pulsing an additive precursor (sub-step) 420 comprising a silicon precursor or a hafnium precursor, pulsing an oxygen reactant (sub-step 430), optionally performing a purge (sub-step 440), optionally repeating sub-steps 410-440 once or a plurality of times (loop 450), pulse a zirconium precursor (sub-step 460), pulsing an oxygen reactant (sub-step 470), optionally pulsing an additive precursor (sub-step 480) comprising a silicon precursor or an aluminum precursor, optionally performing a purge (sub-step 490), and optionally repeating sub-steps 460-490 once or a plurality of times (loop 495).

In some embodiments, sub-steps 410-440 may be performed once or a plurality of times and in any order. In some embodiments, pulsing an oxygen reactant (sub-step 430) is performed after one or more of sub-steps 410 and 420. In some embodiments, pulsing an oxygen reactant (sub-step 430) is performed after one or more of sub-steps 410 and 420 and before another one of sub-steps 410 and 420 is performed. In some embodiments, a purge (sub-step 440) is performed after any or all of the sub-steps 410-430. In some embodiments, sub-steps 410-450 form the first sub-layer. In some embodiments, sub-steps 410-440 constitute a first sub-layer deposition cycle. In some embodiments, the first sub-layer deposition cycle is repeated once or a plurality of times (loop 450).

In some embodiments, sub-steps 460-490 may be performed once or a plurality of times and in any order. In some embodiments, pulsing an oxygen reactant (sub-step 470) is performed after one or more of sub-steps 460 and 480. In some embodiments, pulsing an oxygen reactant (sub-step 470) is performed after one or more of sub-steps 460 and 480 and before another one of sub-steps 460 and 480 is performed. In some embodiments, a purge (sub-step 490) is performed after any or all of the sub-steps 460-480. In some embodiments, sub-steps 460-495 form the second sub-layer. In some embodiments, sub-steps 460-490 constitute a second sub-layer deposition cycle. In some embodiments, the second sub-layer deposition cycle is repeated once or a plurality of times (loop 495).

In some embodiments, the first sub-layer is disposed directly on the interfacial layer. In some embodiments, the first sub-layer is disposed directly on the dipole layer. In some embodiments, the second sub-layer is disposed directly on the first sub-layer. In some embodiments, the dielectric layer consists of the first sub-layer and the second sub-layer. In some embodiments, the first sub-layer has a thickness of about 10 Angstroms to 22 Angstroms, or about 15 Angstroms to about 22 Angstroms. In some embodiments, the second sub-layer has a thickness of about 3 Angstroms to about 10 Angstroms, or about 3 Angstroms to 7 Angstroms.

Not to be bound by theory, it is thought that method 400 may form a dielectric layer that maintains the high band gap of hafnium silicon oxide, hafnium silicate, or hafnium aluminum oxide that interfaces with the interfacial layer, while increasing the dielectric constant of the dielectric layer with a zirconium silicon oxide, a zirconium silicate, or a zirconium oxide. Method 400 may form a dielectric layer with a dielectric constant above 12 (e.g., between 12 and 30, or between 12 and 24, or between 12 and 15, or between 18 and 22).

In some embodiments of step 130, including some embodiments of methods 200, 300, and 400, the hafnium precursor comprises a hafnium halide or a metalorganic hafnium precursor. In some embodiments of step 130, including some embodiments of methods 200, 300, and 400, the zirconium precursor comprises a zirconium halide or a metalorganic zirconium precursor. By way of examples, the hafnium precursor can be or include hafnium chloride or tetrakis(dimethylamino)hafnium, and the zirconium precursor can be or include zirconium chloride. In some embodiments of step 130, including some embodiments of methods 200, 300, and 400, the silicon precursor comprises a silane, a chlorosilane, an organic silane, a heterosilane, or silicon tetrachloride. In some embodiments, the aluminum precursor comprises triethylaluminum (TEA), trimethylaluminum (TMA), dimethylaluminum hydride (DMAH), or aluminum chloride. In some embodiments of step 130, including some embodiments of methods 200, 300, and 400, the oxygen reactant comprises H₂O, O₂, O₃, H₂O₂, NO, NO₂, or N₂O, in any combination.

Turning back to FIG. 1, method 100 continues with forming a dipole layer (step 140). In some embodiments, forming a dipole layer (step 140) occurs before forming a dielectric layer (step 130). In some embodiments, forming a dipole layer (step 140) occurs after forming a dielectric layer (step 130). In some embodiments, forming a dipole layer occurs during forming a dielectric layer (step 130) (e.g., between individual sub-steps of methods 200, 300, or 400). In some embodiments, the dipole layer is formed directly on the dielectric layer. In embodiments where the dielectric layer comprises a second sub-layer comprising a zirconium oxide, zirconium silicon oxide, or zirconium silicate, the dipole layer is disposed directly on the second sub-layer. In some embodiments, the dipole layer is formed directly on the interfacial layer. In some embodiments, the dipole layer is formed in-between sub-layers of the dielectric layer. The dipole layer may be formed by any suitable method, including cyclical deposition processes. In some embodiments, the dipole layer comprises a metal oxide, a metal nitride, or a metal oxynitride. In some embodiments, the dipole layer comprises lanthanum, aluminum, yttrium, scandium, or gallium. In some embodiments, the dipole layer includes lanthanum oxide, aluminum oxide, yttrium oxide, scandium oxide, or gallium oxide.

Method 100 continues with forming a gate electrode (step 150). As used herein, forming a gate electrode may include forming additional layers in a gate stack. Step 150 may include any depositions, etches, anneals, and the like, to complete a gate stack. In some embodiments, the gate electrode comprises a metal nitride, such as TiN or TaN. In some embodiments, the gate electrode comprises a conductive layer. In some embodiments, forming a gate electrode (step 150) comprises forming a layer comprising metal or metal nitride layer, such as TiN directly on the dipole layer. In some embodiments, forming a gate electrode (step 150) comprises forming a layer comprising TiN directly on the dielectric layer.

Various steps of methods described herein can be performed within a single reaction chamber or can be performed in multiple reaction chambers, such as reaction chambers of a cluster tool. In some embodiments, the method 100 may take place in a single reaction space. In some embodiments, one or more sub-steps of method 100 may take place in a different reaction space or a different reaction chamber.

Additionally, a carrier and/or inert gas can be co-flowed throughout methods 100, 200, 300, 400 or during any of the sub-steps of method 100, 200, 300, or 400. By way of example, a carrier and/or an inert gas can be one or more of helium, argon, or nitrogen.

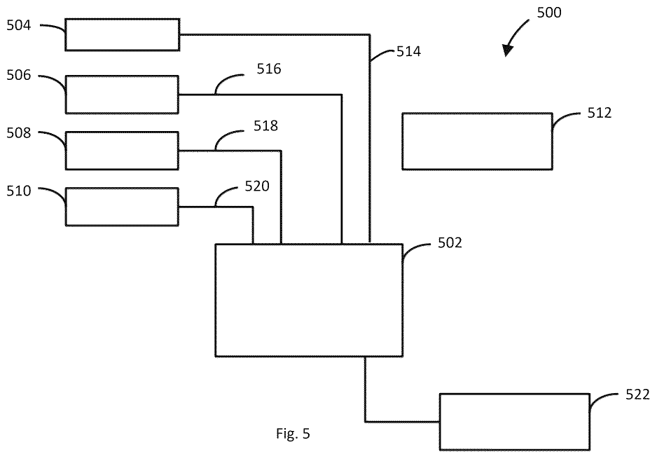

FIG. 5 illustrates an example of a substrate processing apparatus 500 in accordance with one or more examples of the disclosure. Apparatus 500 can be used to perform a method as described herein and/or form a structure or device portion as described herein.

In the illustrated example, apparatus 500 includes one or more reaction chambers 502, a hafnium precursor gas source 504, a zirconium precursor gas source 506, an additive precursor gas source 508, an oxygen reactant gas source 510, an exhaust source 522, and a controller 512.

Reaction chamber 502 can include any suitable reaction chamber, such as an atomic layer deposition (ALD) or chemical vapor deposition (CVD) reaction chamber.

Hafnium precursor gas source 504 can include a vessel and one or more hafnium precursors as described herein—alone or mixed with one or more carrier (e.g., inert) gases. Zirconium precursor gas source 506 can include a vessel and one or more zirconium precursors as described herein—alone or mixed with one or more carrier (e.g., inert) gases. Additive precursor gas source 508 can include a vessel and one or more of silicon or aluminum precursors as described herein—alone or mixed with one or more carrier gases. Oxygen reactant gas source 510 can include one or oxygen reactant gases as described herein. Although illustrated with four gas sources 504-510, apparatus 500 can include any suitable number of gas sources. Gas sources 504-510 can be coupled to reaction chamber 502 via lines 514-520, which can each include flow controllers, valves, heaters, and the like.

Exhaust source 522 can include one or more vacuum pumps.

Controller 512 includes electronic circuitry and software to selectively operate valves, manifolds, heaters, pumps, and other components included in the apparatus 500. Such circuitry and components operate to introduce precursors, reactants, and gases from the respective sources 504-510. Controller 512 can control timing of gas pulse sequences, temperature of the substrate and/or reaction chamber, pressure within the reaction chamber, and various other operations to provide proper operation of the apparatus 500. Controller 512 can include control software to electrically or pneumatically control valves to control flow of precursors, reactants, and purge gases into and out of the reaction chamber 502. Controller 512 can include modules such as a software or hardware component, e.g., a FPGA or ASIC, which performs certain tasks. A module can advantageously be configured to reside on the addressable storage medium of the control system and be configured to execute one or more processes or methods, as described herein.

Other configurations of apparatus 500 are possible, including different numbers and kinds of precursor and reactant sources and purge gas sources. Further, it will be appreciated that there are many arrangements of valves, conduits, precursor sources, and purge gas sources that may be used to accomplish the goal of selectively feeding gases into reaction chamber 502. Further, as a schematic representation of a system, many components have been omitted for simplicity of illustration, and such components may include, for example, various valves, manifolds, purifiers, heaters, containers, vents, and/or bypasses.

During operation of apparatus 500, substrates, such as semiconductor wafers (not illustrated), are transferred from, e.g., a substrate handling system to reaction chamber 502. Once substrate(s) are transferred to reaction chamber 502, one or more gases from gas sources 504-510, such as precursors, reactants, carrier gases, and/or purge gases, are introduced into reaction chamber 502.

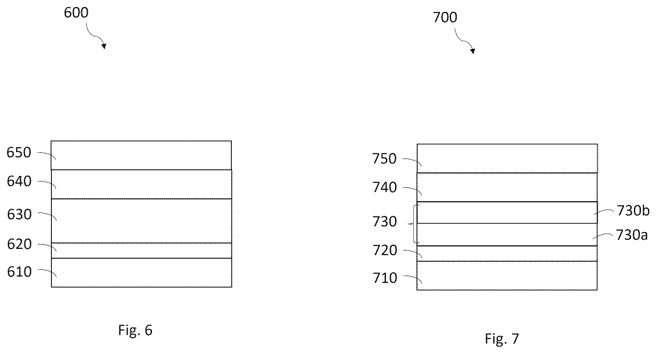

FIG. 6 illustrates a structure/a portion of a device 600 in accordance with additional examples of the disclosure. Device or structure 600 includes a substrate 610, an interfacial layer 620, a dielectric layer 630, a dipole layer 640, and one or more additional layers 650. In some embodiments, device or structure 600 is or is at least part of a gate stack. The interfacial layer 620 may be formed by a method described in this disclosure. In some embodiments, the interfacial layer 620 comprises a silicon oxide. The interfacial layer 620 may have a thickness between about 2 to 10 Angstroms, or about 2 to 7 Angstroms. The dielectric layer 630 may be formed by a method described in this disclosure. In some embodiments, the dielectric layer 630 comprises hafnium, zirconium, silicon, and oxygen. In some embodiments, the dielectric layer 630 comprises hafnium, zirconium, aluminum, and oxygen. In some embodiments, the dielectric layer 630 comprises hafnium, zirconium, silicon, aluminum, and oxygen. In some embodiments, the dielectric layer 630 a hafnium silicon oxide doped with zirconium, a hafnium silicate doped with zirconium, or a hafnium aluminum oxide doped with zirconium. In some embodiments, the dielectric layer 630 may comprise sub-layers of hafnium oxide, silicon oxide, aluminum oxide, and zirconium oxide. In some embodiments, sub-layers comprising silicon oxide or aluminum oxide and sub-layers comprising zirconium oxide are separated by at least one sub-layer of hafnium oxide. In some embodiments, the dielectric layer 630 has a thickness of about 15 Angstroms and about 25 Angstroms, or between about 16 Angstroms and about 20 Angstroms. In some embodiments, the dielectric layer 630 has a dielectric constant greater than about 12, or between about 12 and 30, or between about 12 and 24, or between about 12 and 15, or between about 18 and 22. In some embodiments, the dielectric layer 630 is disposed directly on the interfacial layer 620. The dipole layer 640 may be formed by a method described in this disclosure. In some embodiments, the dipole layer 640 comprises a metal nitride, a metal oxynitride, or a metal oxide, such as lanthanum oxide, yttrium oxide, aluminum oxide, scandium oxide, or gallium oxide. The dipole layer 640 may have a thickness less than 50 Angstroms, or between about 5 Angstroms and 30 Angstroms. In some embodiments, the dipole layer 640 is disposed directly on the dielectric layer 630. Additional layers 650 may include a gate electrode, a barrier or liner layer, and any other layers in the formation of a gate stack. In some embodiments, the additional layers 650 may comprise TiN.

FIG. 7 illustrates a structure/a portion of a device 700 in accordance with additional examples of the disclosure. Device 700 is substantially identical to device 600 except that dielectric layer 730 comprises a first sub-layer 730a and a second sub-layer 730b. First sub-layer 730a is disposed directly on the interfacial layer 720. Second sub-layer 730b is disposed directly on the first sub-layer 730a. Dipole layer 740 is disposed directly on the second sub-layer 730b. First sub-layer 730a comprises a hafnium silicate, hafnium silicon oxide, or hafnium aluminum oxide. Second sub-layer 730b comprises a zirconium oxide, zirconium silicon oxide, or zirconium silicate. First sub-layer 730a may have a thickness between about 10 Angstroms and 22 Angstroms, or about 15 Angstroms and about 22 Angstroms. Second sub-layer 730b may have a thickness between about 3 Angstroms and about 10 Angstroms, or about 3 Angstroms and 7 Angstroms.

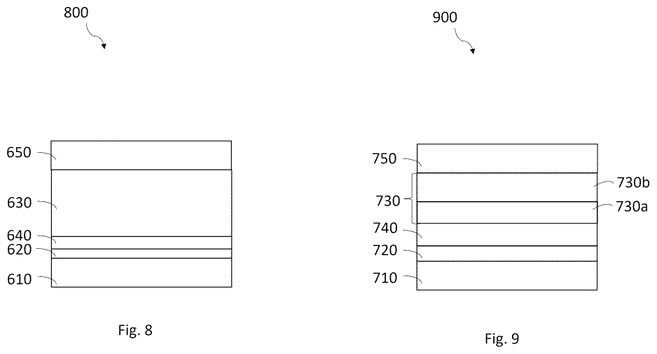

FIG. 8 illustrates a structure/a portion of a device 800 in accordance with additional examples of the disclosure. Device 800 is substantially identical to device 600 except that dipole layer 640 is disposed between the interfacial layer 620 and the dielectric layer 630.

FIG. 9 illustrates a structure/a portion of a device 900 in accordance with additional examples of the disclosure. Device 900 is substantially identical to device 700 except that Dipole layer 740 is disposed between the interfacial layer 720 and first sub-layer 730a the dielectric layer 730.

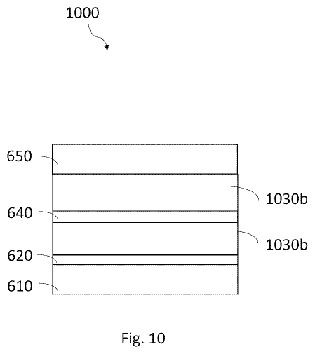

FIG. 10 illustrates a structure/a portion of a device 1000 in accordance with additional examples of the disclosure. Device 1000 is substantially identical to device 600 except that dipole layer 640 is disposed as layer in-between the sub-layers 1030a and 1030b of the dielectric layer. Sub-layers 1030a and 1030b may be any sub-layers of the dielectric layer as described herein.

The example embodiments of the disclosure described above do not limit the scope of the invention, since these embodiments are merely examples of the embodiments of the invention, which is defined by the appended claims and their legal equivalents. Any equivalent embodiments are intended to be within the scope of this invention. Indeed, various modifications of the disclosure, in addition to those shown and described herein, such as alternative useful combinations of the elements described, may become apparent to those skilled in the art from the description. Such modifications and embodiments are also intended to fall within the scope of the appended claims.

1. A method for forming a gate stack, the method comprising:
providing a substrate comprising a surface comprising an interfacial layer in a reaction chamber; and
forming a dielectric layer on the interfacial layer by an atomic layer deposition process, wherein forming the dielectric layer comprises pulsing a hafnium precursor a plurality of times, pulsing a zirconium precursor at least once, pulsing an additive precursor at least once, and pulsing an oxygen reactant,
wherein the additive precursor comprises a silicon precursor or an aluminum precursor, and
wherein the hafnium precursor is pulsed at least once between each pulse of the zirconium precursor and each pulse of the additive precursor.

2. The method of claim 1, wherein the dielectric layer comprises a plurality of sub-layers comprising a first sub-layer comprising hafnium oxide, a second sub-layer comprising silicon oxide or aluminum oxide, a third sub-layer comprising hafnium oxide, and a fourth sub-layer comprising zirconium oxide, and
wherein the second sub-layer and the fourth sub-layer are not in direct contact with each other.

3. The method of claim 1, wherein forming the dielectric layer comprises performing a plurality of first cycles, wherein the first cycle comprises, in order:
pulsing the hafnium precursor for a first period,
pulsing the additive precursor,
pulsing the hafnium precursor for a second period, and
pulsing the zirconium precursor.

4. The method of claim 3, wherein the zirconium precursor is not pulsed before the second period, and wherein the additive precursor is not pulsed before the first period or after the second period in the first cycle.

5. The method of claim 3, wherein a ratio of number of pulses of the additive precursor to a number of pulses of the zirconium precursor in the first cycle is in a range of about 2.5:1 to about 4:1.

6. The method of claim 3, wherein a ratio of number of pulses of the hafnium precursor to a number of pulses of the zirconium precursor in the first cycle is in a range of about 1.5:1 to about 2.5:1.

7. The method of claim 3, wherein a ratio of a number of pulses of the additive precursor to a number of pulses of the hafnium precursor in the first cycle is in a range of about 1.25:1 to 1.75:1.

8. The method of claim 1, further comprising forming a dipole layer directly on the dielectric layer.

9. The method of claim 8, wherein the dipole layer comprises lanthanum oxide, aluminum oxide, yttrium oxide, scandium oxide, or gallium oxide.

10. The method of claim 1, further comprising forming a dipole layer directly on the interfacial layer.

11. The method of claim 1, wherein a ratio of oxygen atoms to a sum of hafnium, zirconium, aluminum, and silicon atoms is in a range of about 1.6:1 to about 2.5:1.

12. The method of claim 1, wherein the additive precursor comprises a silicon precursor.

13. A method for forming a gate stack, the method comprising:
providing a substrate comprising a surface comprising an interfacial layer in a reaction chamber; and
forming a dielectric layer on the interfacial layer by an atomic layer deposition process, wherein the dielectric layer comprises a first sub-layer comprising hafnium silicate, hafnium silicon oxide, or hafnium aluminum oxide disposed directly on the interfacial layer and a second sub-layer comprising zirconium oxide, zirconium silicon oxide, or zirconium silicate disposed directly on the first sub-layer.

14. The method of claim 13, further comprising forming a dipole layer directly on the second sub-layer, wherein the dipole layer comprises lanthanum oxide, aluminum oxide, yttrium oxide, scandium oxide, or gallium oxide.

15. The method of claim 13, wherein the dielectric layer has a thickness between about 15 Angstroms and about 25 Angstroms.

16. The method of claim 13, wherein the interfacial layer comprises silicon oxide.

17. The method of claim 13, wherein the dielectric layer has a dielectric constant in a range of about 12 to about 30.

18. A method for forming a gate stack, the method comprising:
providing a substrate comprising a surface comprising an interfacial layer in a reaction chamber; and
forming a dielectric layer on the interfacial layer by an atomic layer deposition process, wherein forming the dielectric layer comprises pulsing a hafnium precursor a plurality of times, pulsing a zirconium precursor at least once, pulsing an additive precursor at least once, and pulsing an oxygen reactant,
wherein the additive precursor comprises a silicon precursor or an aluminum precursor, and
wherein the dielectric layer comprises a hafnium silicon oxide doped with zirconium, a hafnium silicate doped with zirconium, or a hafnium aluminum oxide doped with zirconium, wherein a ratio of a number of pulses of hafnium precursor to a number of pulses of the zirconium precursor during forming the dielectric layer is about 30:1 to about 7:1.

19. The method of claim 18, wherein the additive precursor comprises a silicon precursor.

20. The method of claim 18, further comprising forming a dipole layer directly on the dielectric layer.
